(19) United States
(12) Patent Application Publication
(10) Pub. No.: US 2024/0006456 A1
(43) Pub. Date: Jan. 4, 2024

(54) DEVICE, SYSTEM, AND MOVING BODY

(71) Applicant: CANON KABUSHIKI KAISHA, Tokyo (JP)

(72) Inventor: KAZUHIRO MORIMOTO, Kanagawa (JP)

(21) Appl. No.: 18/341,644

(22) Filed: Jun. 26, 2023

(30) Foreign Application Priority Data
Jun. 29, 2022 (JP) 2022-104637

(51) Int. Cl. H01L 27/146; H01L 31/107

(52) U.S. Cl. CPC H01L 27/14649; H01L 31/107; H01L 27/1463; H01L 31/103

(57) ABSTRACT

A device includes a first substrate including a first layer including a first surface and a second surface, and a first wiring structure located on the first layer. The device includes an avalanche photodiode located on the first layer, and a resistive element connected to the avalanche photodiode. The first wiring structure includes a wire to supply a first voltage to the avalanche photodiode. A distance between the resistive element and the first surface of the first layer is greater than a distance between the wire and the first surface of the first layer.

### BACKGROUND

### Technical Field

The aspect of the embodiments relates to a device, a system incorporating the device, and a moving body.

### Description of the Related Art

To cause a photoelectric conversion device incorporating an avalanche photodiode (APD) to operate in a Geiger mode, a method is known of disposing a fine resistor (quenching element) made of a material, such as polycrystalline silicon, on the surface of a semiconductor layer provided with the APD.

In a configuration discussed in Japanese Patent Application Laid-Open No. 2010-226073, particularly, in a case of using minute pixels, a potential of a quenching element disposed near an APD and variations in the potential have an adverse effect on an electrostatic potential, which leads to an increase in noise.

### SUMMARY

According to an aspect of the embodiments, a device includes a first substrate including a first layer including a first surface and a second surface, and a first wiring structure located on the first layer. The device includes an avalanche photodiode located on the first layer, and a resistive element connected to the avalanche photodiode. The first wiring structure includes a wire to supply a first voltage to the avalanche photodiode. A distance between the resistive element and the first surface of the first layer is greater than a distance between the wire and the first surface of the first layer.

Further features of the disclosure will become apparent from the following description of exemplary embodiments with reference to the attached drawings.

### BRIEF DESCRIPTION OF THE DRAWINGS

FIG. 1 is a schematic view illustrating a configuration example of a photoelectric conversion device according to an exemplary embodiment.

FIG. 2 is a schematic view of a sensor substrate of the photoelectric conversion device according to the exemplary embodiment.

FIG. 3 is a schematic view of a circuit substrate of the photoelectric conversion device according to the exemplary embodiment.

FIG. 4 is a circuit diagram illustrating a configuration example of a pixel circuit of the photoelectric conversion device according to the exemplary embodiment.

FIGS. 5A to 5C each schematically illustrate driving of the pixel circuit of the photoelectric conversion device according to the exemplary embodiment.

FIG. 6 is a sectional view of a pixel unit in a photoelectric conversion device according to a first exemplary embodiment.

FIGS. 7A and 7B are plan views each illustrating the pixel unit in the photoelectric conversion device according to the first exemplary embodiment.

FIG. 8 is a circuit diagram illustrating a configuration example of a pixel circuit in a photoelectric conversion device according to a second exemplary embodiment.

FIG. 9 is a sectional view of the pixel unit in the photoelectric conversion device according to the second exemplary embodiment.

FIGS. 10A and 10B are plan views each illustrating the pixel unit in the photoelectric conversion device according to the second exemplary embodiment.

FIG. 11 illustrates sectional views of a photoelectric conversion device according to a modified example of the second exemplary embodiment.

FIG. 12 is a circuit diagram illustrating a configuration example of a pixel circuit in a photoelectric conversion device according to a third exemplary embodiment.

FIG. 13 is a sectional view of the pixel unit in the photoelectric conversion device according to the third exemplary embodiment.

FIGS. 14A and 14B are plan views each illustrating the pixel unit in the photoelectric conversion device according to the second exemplary embodiment.

FIG. 15 is a functional block diagram illustrating a photoelectric conversion system according to a fourth exemplary embodiment.

FIGS. 16A and 16B are functional block diagrams illustrating a photoelectric conversion system according to a fourth exemplary embodiment.

FIG. 17 is a functional block diagram illustrating a photoelectric conversion system according to a seventh exemplary embodiment.

FIG. 18 is a functional block diagram illustrating a photoelectric conversion system according to a seventh exemplary embodiment.

FIGS. 19A and 19B are perspective views illustrating a photoelectric conversion system according to an eighth exemplary embodiment.

### DESCRIPTION OF THE EMBODIMENTS

The following exemplary embodiments are exemplified to embody the technical idea of the disclosure, and are not intended to limit the disclosure. The sizes and positional relationships of members illustrated in the drawings may be exaggerated for clarity of illustration. In the following description, the same components are denoted by the same reference numerals, and descriptions thereof may be omitted.

Exemplary embodiments of the disclosure will be described in detail below with reference to the drawings. In the following description, terms describing specific directions or positions (such as “up”, “down”, “right”, and “left”, and other phrases including these terms) are used as appropriate. In one embodiment, such terms and phrases are used to facilitate the understanding of the exemplary embodiments with reference to the drawings, and the technical scope of the disclosure is not limited by the meaning of the terms or phrases.

The term “planar view” used herein refers to a view taken in a direction perpendicular to a light incident surface of a semiconductor layer. The term “cross section” refers to a plane in the direction perpendicular to the light incident surface of the semiconductor layer. If the light incident surface of the semiconductor layer is microscopically rough, the plan view is defined with reference to the light incident surface of the semiconductor layer seen macroscopically.

In the following description, the anode of an avalanche photodiode (APD) is fixed to a potential, and a signal is taken out of the cathode of the APD. A semiconductor region of a first conductivity type where charges having the same polarity as that of signal charges are the majority carriers refers to an n-type semiconductor region. A semiconductor region of a second conductivity type where charges having the opposite polarity to that of signal charges are the majority carriers refers to a p-type semiconductor region. An exemplary embodiment of the disclosure also holds if the cathode of an APD is fixed to a potential and a signal is taken out of the anode of the APD. In this case, the semiconductor region of the first conductivity type where charges having the same polarity as that of signal charges are the majority carriers refers to the p-type semiconductor region. The semiconductor region of the second conductivity type where charges having the opposite polarity to that of signal charges are the majority carriers refers to the n-type semiconductor region. In the following description, either one of the nodes of the APD is fixed to a potential. However, the both nodes of the APD can be variable in potential.

The term “impurity concentration” used herein refers to the net impurity concentration compensated for impurities of opposite conductivity type. In other words, the “impurity concentration” refers to a net doping concentration. A region where the p-type doping impurity concentration is higher than the n-type doping impurity concentration is a p-type semiconductor region. In contrast, a region where the n-type doping impurity concentration is higher than the p-type doping impurity concentration is an n-type semiconductor region.

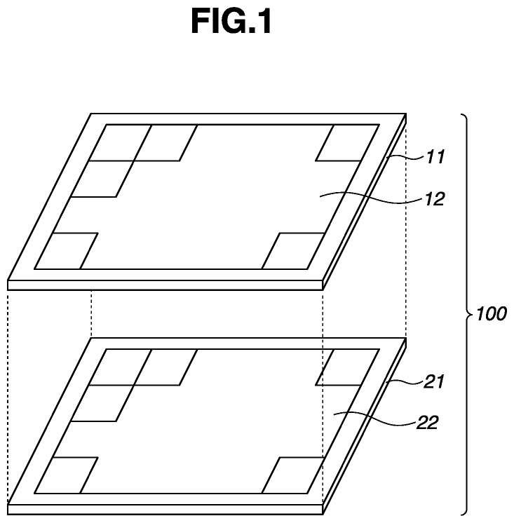

A configuration common to exemplary embodiments of a photoelectric conversion device that can be used with a processing apparatus according to the disclosure and a driving method therefor will be described with reference to FIGS. 1 to 5C. The present exemplary embodiment illustrates an example of the processing apparatus provided outside the photoelectric conversion device. However, the processing apparatus can be provided in the photoelectric conversion device, for example.

FIG. 1 is a schematic view illustrating a configuration example of a lamination-type photoelectric conversion device 100 according to an exemplary embodiment of the disclosure.

The photoelectric conversion device 100 has a configuration in which two substrates, e.g., a sensor substrate 11 serving as a first substrate and a circuit substrate 21 serving as a second substrate, are stacked and electrically connected to each other. The sensor substrate 11 includes a first semiconductor layer including photoelectric conversion elements 102 to be described below, and a first wiring structure. The circuit substrate 21 includes a second semiconductor layer including circuits, such as signal processing units 103 described below, and a second wiring structure. The photoelectric conversion device 100 is formed by stacking the second semiconductor layer, the second wiring structure, the first wiring structure, and the first semiconductor layer in this order. The photoelectric conversion device 100 according to each exemplary embodiment is a back-illuminated photoelectric conversion device having a configuration in which light is incident on a first surface and a circuit substrate is disposed on a second surface.

In the following description, the sensor substrate 11 and the circuit substrate 21 are described as diced chips. However, the sensor substrate 11 and the circuit substrate 21 are not limited to chips. For example, the sensor substrate 11 and the circuit substrate 21 can be wafers. The sensor substrate 11 and the circuit substrate 21 that are in a wafer state can be stacked before dicing. Diced chips can be stacked and bonded.

The sensor substrate 11 includes a pixel region 12. The circuit substrate 21 includes a circuit region 22 for processing a signal detected in the pixel region 12.

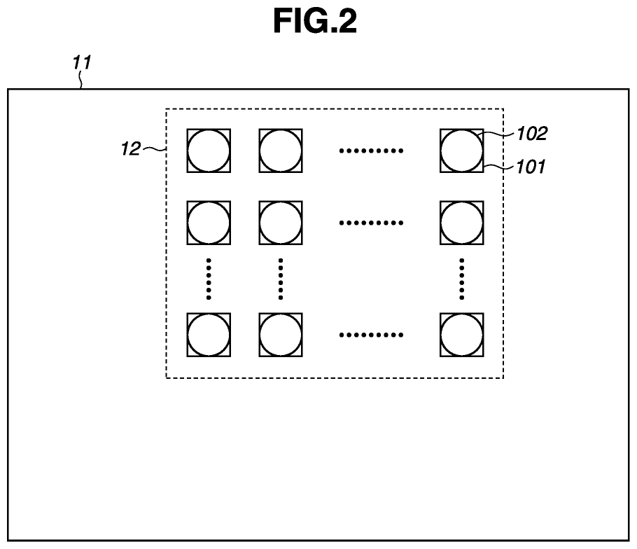

FIG. 2 illustrates a layout example of the sensor substrate 11. Pixels 101 each including the photoelectric conversion element 102 including an APD are arranged in a two-dimensional array in a planar view, thereby forming the pixel region 12.

Typically, the pixels 101 are used for forming an image. However, in time of flight (ToF) applications, the pixels 101 do not necessarily need to form an image. Specifically, the pixels 101 can be used to measure the time of arrival of light and the amount of the light.

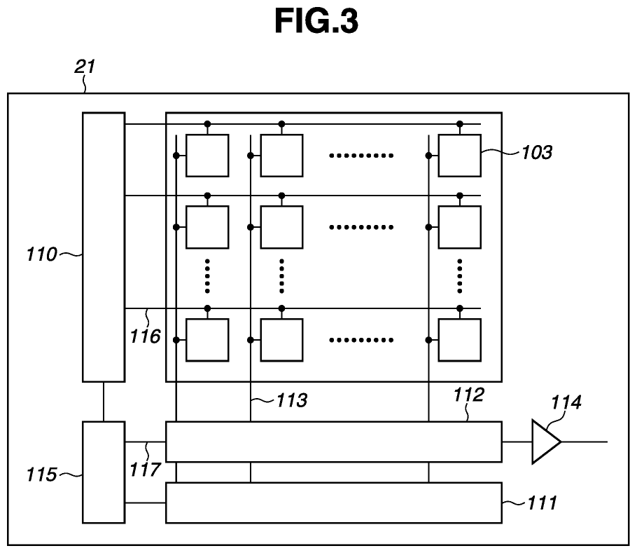

FIG. 3 is a configuration diagram of the circuit substrate 21. The circuit substrate 21 includes the signal processing units 103, a readout circuit 112, a control pulse generation unit 115, a horizontal scanning circuit 111, signal lines 113, and a vertical scanning circuit 110. The signal processing units 103 performs processing charges photoelectrically converted by the photoelectric conversion elements 102 illustrated in FIG. 2.

The photoelectric conversion elements 102 illustrated in FIG. 2 and the signal processing units 103 illustrated in FIG. 3 are electrically connected via connection wires provided for the respective pixels 101.

The vertical scanning circuit 110 receives a control pulse supplied from the control pulse generation unit 115, and supplies the control pulse to each pixel 101. Logic circuits, such as a shift register and an address decoder, are used for the vertical scanning circuit 110.

The signal output from the photoelectric conversion element 102 in each pixel 101 is processed by the corresponding signal processing unit 103. Each signal processing unit 103 is provided with a counter, a memory, and the like, and the memory holds digital values.

The horizontal scanning circuit 111 inputs control pulses for sequentially selecting columns to the signal processing units 103 to read out digital signals from the memories of the respective pixels 101 in which the digital signals are stored.

The signal processing unit 103 of the pixel 101 selected by the vertical scanning circuit 110 in the selected column outputs a signal to the corresponding signal line 113.

The signal output to the signal line 113 is output to a storage unit or a signal processing unit that is located outside the photoelectric conversion device 100 via an output circuit 114.

In the configuration illustrated in FIG. 2, the photoelectric conversion elements 102 can be one-dimensionally arranged in the pixel region 12. The functions of the signal processing units 103 do not necessarily need to be provided for all the photoelectric conversion elements 102 on a one-on-one basis. For example, a plurality of photoelectric conversion elements 102 can share one signal processing unit 103, and signal processing can be sequentially performed.

As illustrated in FIGS. 2 and 3, the plurality of signal processing units 103 is provided in a region overlapping the pixel region 12 in a planar view. The vertical scanning circuit 110, the horizontal scanning circuit 111, the readout circuit 112, the output circuit 114, and the control pulse generation unit 115 are provided to overlap the region between the ends of the sensor substrate 11 and the ends of the pixel region 12 in a planar view. In other words, the sensor substrate 11 includes the pixel region 12 and a non-pixel region located around the pixel region 12. The vertical scanning circuit 110, the horizontal scanning circuit 111, the readout circuit 112, the output circuit 114, and the control pulse generation unit 115 are provided in a region overlapping the non-pixel region in a planar view.

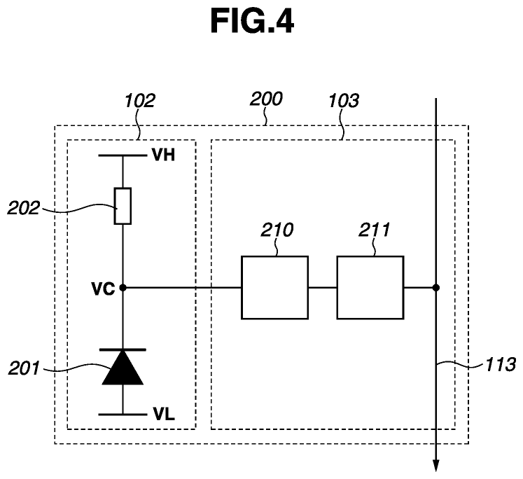

FIG. 4 illustrates an example of a circuit diagram including equivalent circuits illustrated in FIGS. 2 and 3.

As illustrated in FIG. 2, a photoelectric conversion element 102 including an APD 201 is provided on the sensor substrate 11, and the other members are provided on the circuit substrate 21.

The APD 201 is a photoelectric conversion unit that generates charge pairs corresponding to incident light by photoelectrical conversion.

The anode of the APD 201 is supplied with a voltage VL (first voltage). The cathode of the APD 201 is supplied with a voltage VH (second voltage) that is higher than the voltage VL supplied to the anode of the APD 201. A reverse bias voltage for causing the APD 201 to perform an avalanche multiplication operation is supplied to the anode and the cathode of the APD 201. With the voltage supplied, the charges generated by the incident light cause avalanche multiplication, thereby generating an avalanche current. Power supply wires of two channels to supply voltages to each of the cathode and the anode of the APD 201 are provided on the first substrate.

The reverse bias voltage can be supplied in a Geiger mode and a linear mode. In the Geiger mode, the APD 201 operates with a potential difference greater than the breakdown voltage between the anode and the cathode of the APD 201. In the linear mode, the APD 201 operates with a voltage difference close to the breakdown voltage or less between the anode and the cathode of the APD 201.

An APD operating in the Geiger mode is referred to as a single-photon avalanche diode (SPAD). For example, the voltage VL (first voltage) is −30 V (volts), and the voltage VH (second voltage) is 1 V. The APD 201 can be operated in the linear mode or the Geiger mode. The SPAD may be desirable because the SPAD has a higher potential difference and a more significant effect of improving a signal-to-noise ratio compared to the APD in the linear mode.

A resistive element 202 is connected to a node between a power supply for supplying the voltage VH and the APD 201. The resistive element 202 functions as a load circuit (quenching circuit) in multiplying a signal by avalanche multiplication, and reduces the voltage supplied to the APD 201 to suppress the avalanche multiplication (quenching operation). The resistive element 202 also has the function of restoring the voltage to be supplied to the APD 201 to the voltage VH (recharging operation) by passing a current corresponding to a voltage drop caused by the quenching operation.

A signal processing unit 103 includes a waveform shaping unit 210 and a counter circuit 211. In the present exemplary embodiment, the signal processing unit 103 can include at least one of the waveform shaping unit 210 and the counter circuit 211.

The waveform shaping unit 210 shapes the waveform of a potential change of the cathode of the APD 201 obtained upon detection of a photon, and outputs a pulse signal. For example, an inverter circuit is used as the waveform shaping unit 210. A circuit including a plurality of inverters connected in series can be used. Other circuits having the waveform shaping effect can also be used.

The counter circuit 211 counts the pulse signal output from the waveform shaping unit 210 and holds the count value.

A switch, such as a transistor, can also be provided between the resistive element 202 and the APD 201 or between the photoelectric conversion element 102 and the signal processing unit 103 to switch the electrical connection. Similarly, the voltage VH or the voltage VL to be supplied to the photoelectric conversion element 102 can also be electrically switched using a switch, such as a transistor.

While the present exemplary embodiment illustrates a configuration example using the counter circuit 211, the photoelectric conversion device 100 can acquire a pulse detection timing using a time-to-digital converter (TDC) and a memory, instead of the counter circuit 211. In this case, the generation timing of the pulse signal output from the waveform shaping unit 210 is converted into a digital signal by the TDC. The TDC is supplied with a control pulse pREF (reference signal) via a drive line from the vertical scanning circuit 110 illustrated in FIG. 3 to measure the pulse signal timing. The TDC acquires the input timing of the signal output from each pixel 101 via the waveform shaping unit 210 as a digital signal when the input timing is a relative timing with reference to the control pulse pREF.

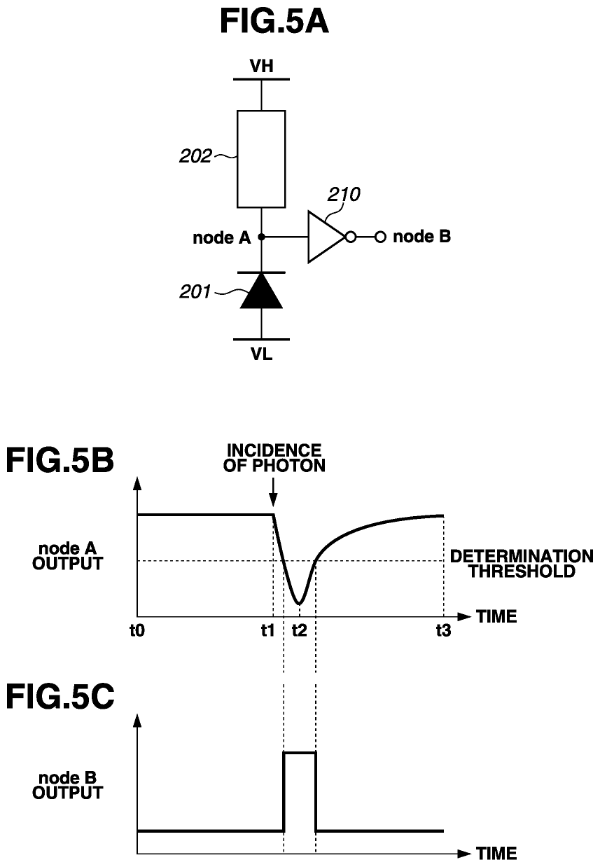

FIGS. 5A to 5C each schematically illustrate a relationship between an operation of the APD 201 and an output signal.

FIG. 5A schematically illustrates the APD 201, the resistive element 202, and the waveform shaping unit 210 illustrated in FIG. 4. Assume herein that the input side of the waveform shaping unit 210 is referred to as a node A, and the output side of the waveform shaping unit 210 is referred to as a node B.

FIG. 5B illustrates a waveform change of the node A illustrated in FIG. 5A. FIG. 5C illustrates a change in the waveform of the node B illustrated in FIG. 5A.

During a period between time t0 and time t1, a potential difference VH-VL is applied to the APD 201 illustrated in FIG. 5A. If a photon is incident on the APD 201 at time t1, avalanche multiplication occurs in the APD 201 and an avalanche multiplication current flows to the resistive element 202, so that the voltage of the node A drops. When the amount of voltage drop further increases and the potential difference applied to the APD 201 decreases, the avalanche multiplication by the APD 201 stops as indicated at time t2, and the voltage level of the node A stops dropping beyond a certain value. Thereafter, a current to compensate for the voltage drop from the voltage VL flows to the node A during a period between time t2 and time t3. At time t3, the node A settles at the original potential level. In this case, the portion of the output waveform at the node A falling below a certain threshold is shaped by the waveform shaping unit 210 and is output to the node B as a signal.

The layout of the signal lines 113 and the layout of the readout circuit 112 and the output circuit 114 are not limited to those illustrated in FIG. 3. For example, the signal lines 113 can be located to extend in a row direction, and the readout circuit 112 can be located at the end of each signal line 113.

Photoelectric conversion devices according to exemplary embodiments will be described below.

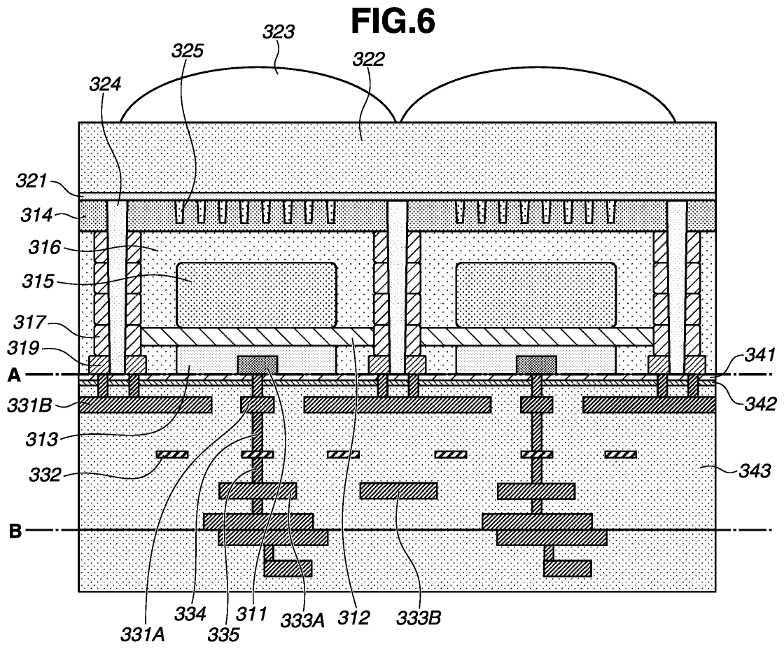

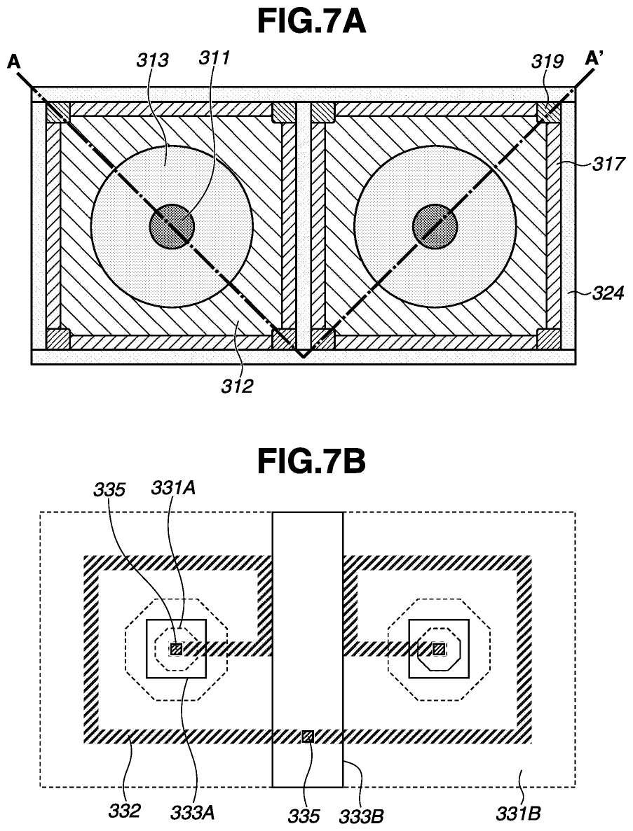

A photoelectric conversion device according to a first exemplary embodiment will be described with reference to FIG. 6 and FIGS. 7A and 7B.

FIG. 6 is a sectional view of the photoelectric conversion elements 102 corresponding to two pixels 101 taken in a direction perpendicular to a substrate surface direction in the photoelectric conversion device according to the present exemplary embodiment. FIG. 6 corresponds to a cross section taken along a line A-A′ illustrated in FIG. 7A.

A structure and functions of each photoelectric conversion element 102 will now be described. Each photoelectric conversion element 102 includes a first semiconductor region 311, a third semiconductor region 313, a fifth semiconductor region 315, and a sixth semiconductor region 316 as n-type semiconductor regions. Each photoelectric conversion element 102 further includes a second semiconductor region 312, a fourth semiconductor region 314, a seventh semiconductor region 317, and a ninth semiconductor region 319 as p-type semiconductor regions.

According to the present exemplary embodiment, in the cross section illustrated in FIG. 6, the n-type first semiconductor region 311 is formed in the vicinity of the surface opposed to the light incident surface, and the n-type third semiconductor region 313 is formed in the vicinity of the n-type first semiconductor region 311. The p-type second semiconductor region 312 is formed at a location where the second semiconductor region 312 overlaps the first semiconductor region 311 in a planar view. The n-type fifth semiconductor region 315 is further provided at a location overlapping the second semiconductor region 312 in a planar view, and the n-type sixth semiconductor region 316 is formed in the vicinity of the fifth semiconductor region 315.

The first semiconductor region 311 has an n-type impurity concentration higher than that of the third semiconductor region 313 and the fifth semiconductor region 315. The p-type second semiconductor region 312 and the n-type first semiconductor region 311 form a PN junction therebetween. The second semiconductor region 312 has a lower impurity concentration than that of the first semiconductor region 311, so that the entire portion of the second semiconductor region 312 overlapping the center of the first semiconductor region 311 in a planar view constitutes a depletion layer region. In this case, a potential difference between the first semiconductor region 311 and the second semiconductor region 312 is greater than a potential difference between the second semiconductor region 312 and the fifth semiconductor region 315. The depletion layer region further extends to a part of the first semiconductor region 311, and a high electric field is induced in the extended depletion layer region. This electric field causes avalanche multiplication in the depletion layer region extending to a part of the first semiconductor region 311, and a current based on the multiplied charge is output as a signal charge. Light incident on the photoelectric conversion element 102 is photoelectrically converted to cause avalanche multiplication in the depletion layer region (avalanche multiplication region), and the generated charges of the first conductivity type are collected to the first semiconductor region 311.

In the configuration illustrated in FIG. 6, the third semiconductor region 313 and the fifth semiconductor region 315 are formed with a similar size. However, the size of each of the third semiconductor region 313 and the fifth semiconductor region 315 is not limited to this size. For example, the fifth semiconductor region 315 can be formed with a size larger than that of the third semiconductor region 313 to collect charges to the first semiconductor region 311 from a wider area.

The third semiconductor region 313 can be a p-type semiconductor region instead of an n-type semiconductor region. In this case, the impurity concentration of the third semiconductor region 313 is set to be lower than the impurity concentration of the second semiconductor region 312. This is because, if the impurity concentration of the third semiconductor region 313 is extremely high, an avalanche multiplication region can be formed between the third semiconductor region 313 and the first semiconductor region 311, which increases a dark count rate (DCR).

A concavo-convex structure 325 made of trenches is formed in the surface corresponding to the light incident surface of the semiconductor layer. The concavo-convex structure 325 is surrounded by the p-type fourth semiconductor region 314, and scatters the light incident on the photoelectric conversion element 102. The incident light travels obliquely in the photoelectric conversion element 102, so that an optical path length greater than or equal to the thickness of the semiconductor layer can be secured. This enables photoelectric conversion of light with a longer wavelength than that without the concavo-convex structure 325. The concavo-convex structure 325 also prevents reflection of the incident light inside the substrate, so that the effect of improving the photoelectric conversion efficiency of the incident light is obtained. The concavo-convex structure 325 can further improve near-infrared sensitivity because a wiring portion located near the surface opposed to the light incident surface can efficiently reflect light obliquely diffracted by the concavo-convex structure 325.

The fifth semiconductor region 315 and the concavo-convex structure 325 are formed to overlap each other in a planar view. An area where the fifth semiconductor region 315 and the concavo-convex structure 325 overlap each other in a planar view is larger than the area of the fifth semiconductor region 315 that does not overlap the concavo-convex structure 325. A charge generated at a location far from the avalanche multiplication region formed between the first semiconductor region 311 and the fifth semiconductor region 315 takes a longer traveling time to reach the avalanche multiplication region compared to that taken by a charge generated at a location near the avalanche multiplication region. This may increase timing jitter. Locating the fifth semiconductor region 315 and the concavo-convex structure 325 to overlap each other in a planar view makes it possible to increase the electric field in a deep part of the photodiode and to reduce the time for collecting charges generated at locations far from the avalanche multiplication region. Consequently, timing jitter can be reduced.

The fourth semiconductor region 314 three-dimensionally covers the concavo-convex structure 325, thereby preventing the generation of thermally excited charges at an interface of the concavo-convex structure 325. This can reduce the DCR of the photoelectric conversion element 102.

The pixels 101 are isolated by trenched pixel isolation portions 324. The p-type seventh semiconductor region 317 formed around the pixel isolation portions 324 isolates the adjacent photoelectric conversion elements 102 from each other with a potential barrier. The photoelectric conversion elements 102 are also isolated by the potential of the seventh semiconductor region 317. Accordingly, a trench structure, such as the pixel isolation portion 324, is not necessarily indispensable. Even if the trenched pixel isolation portions 324 are provided, the depth and position of the trenched pixel isolation portions 324 are not limited to those in the configuration illustrated in FIG. 6. The pixel isolation portions 324 can be deep trench isolation (DTI) that penetrates the semiconductor layer or DTI that does not penetrate the semiconductor layer. Metal can be embedded in the DTI to improve light shielding performance. Each pixel isolation portion 324 can be formed of a silicon monoxide (SiO), a fixed charge film, a metal member, polycrystalline silicon, or a combination of two or more of these. The pixel isolation portions 324 can be configured to surround the entire peripheries of the photoelectric conversion elements 102 in a planar view. For example, the pixel isolation portions 324 can be located only at the opposite sides of the photoelectric conversion elements 102. A voltage can be applied to the embedded members to induce charges at the trench interface to reduce the DCR.

The distance from one pixel isolation portion 324 to the pixel isolation portion 324 provided in an adjoining pixel 101 or a pixel 101 located at the nearest position can also be regarded as the size of one photoelectric conversion element 102. When the size of one photoelectric conversion element 102 is represented by L, a distance d from the light incident surface to the avalanche multiplication region satisfies L √2/4<d<L×√2. If the size and depth of the photoelectric conversion element 102 satisfy this formula, the strength of the electric field in the depth direction and the strength of the electric field in the planar direction in the vicinity of the first semiconductor region 311 are at similar levels. This reduces variations in the time for collecting charges, and thus can improve timing jitter.

A pinning film 321, a planarization film 322, and microlenses 323 are further formed on the light incident surface of the semiconductor layer. A filter layer (not illustrated) and the like can be further located on the light incident surface. Various optical filters, such as a color filter, an infrared cutoff filter, and a monochrome filter, can be used for the filter layer. Examples of the color filter include a red-green-blue (RGB) filter and a red-green-blue-white (RGBW) filter.

On the surface of the semiconductor layer that is opposed to the light incident surface, a wiring structure including a conductor and an insulating film is provided. Each photoelectric conversion element 102 illustrated in FIG. 6 further includes an oxide film 341 and a protective film 342 that are formed in this order from the nearest side of the semiconductor layer. Wiring layers each formed of a conductor are further stacked thereon. A wiring interlayer film 343 that is an insulating film is located between the wire and the semiconductor layer and between the wiring layers. The protective film 342 is used for protecting the APD 201 from plasma damage or metal contamination during etching. A nitride film made of silicon nitride (SiN) is typically used, but instead a silicon oxynitride (SiON) film, a silicon carbide (SiC) film, a silicon carbonitride (SiCN) film, or the like can be used.

A cathode wire 331A is connected to the first semiconductor regions 311. An anode wire 331B supplies a voltage to the seventh semiconductor region 317 via the ninth semiconductor region 319 functioning as an anode contact. In the present exemplary embodiment, the cathode wire 331A and the anode wire 331B are located in the same wiring layer. The wiring portion is formed of a conductor containing metal, such as copper (Cu) or aluminum (Al), as a major material.

A resistive element 332 is connected to the cathode wire 331A and functions as a quenching resistor. In this case, the resistive element 332 is formed on the opposite side of a semiconductor substrate as viewed from the cathode wire 331A and an anode wire 331B. As a material for the resistive element 332, a silicon-based material, such as polycrystalline silicon or amorphous silicon, a transparent electrode made of an inorganic material, a metal thin-film material such as nichrome (NiCr), ceramic materials, such as a titanium nitride (TiN), a tantalum nitride (TaN), a tantalum silicon (TaSi), or a tungsten nitride (WN), an organic material, and the like can be used. The material for the resistive element 332 may have a resistivity higher than that of the major material used for the cathode wire 331A and the anode wire 331B. A wiring portion 333A is connected to the resistive element 332 through a via hole 335. A wiring portion 333B is a wire provided in the same wiring layer as the wiring portion 333A.

FIGS. 7A and 7B are plan views each illustrating two pixels 101 in the photoelectric conversion device according to the first exemplary embodiment. FIG. 7A is a plan view of each semiconductor region in a planar view from the surface opposed to the light incident surface. FIG. 7B is a plan view of a wiring portion in a planar view from the surface opposed to the light incident surface.

As illustrated in FIG. 7A, the first semiconductor region 311, the third semiconductor region 313, and the fifth semiconductor region 315 are circular in shape and are concentrically arranged. This structure provides the effect of reducing the DCR by reducing the local concentration of the electric field at the ends of the high field area between the first semiconductor region 311 and the second semiconductor region 312. The shape of each of the first semiconductor region 311, the third semiconductor region 313, and the fifth semiconductor region 315 is not limited to the circular shape. For example, the first semiconductor region 311, the third semiconductor region 313, and the fifth semiconductor region 315 can have polygonal shapes with the same barycentric positions.

As illustrated in FIG. 7B, the resistive element 332 is formed in a narrow line pattern, and is electrically connected to each of the cathode wire 331A and the wiring portion 333B through a via hole and a wiring layer. The via hole 335 is formed on the resistive element 332 and is electrically connected to the wiring portion 333A. The wiring portion 333A is electrically connected to the signal processing unit 103, which is disposed on the circuit substrate 21, through a connection wire provided for each pixel 101. The resistance value of the resistive element 332 may be set to a sufficiently high level to quench the multiplication current of the APD 201. In one embodiment, a resistance of at least 10 kOhm (kilo ohms) is set. The resistance value of the resistive element 332 may be set to, for example, 50 kOhm or more, but instead may be about 30 kOhm. In view of the time required for recovery from a change in the potential due to the occurrence of avalanche multiplication, the resistance value, in one embodiment, may be less than or equal to 1 MOhm (mega ohms). To achieve a higher resistance value within a limited pixel area, the sectional area of the resistive element 332 is to be minimized. For example, the thickness with respect to the width of the resistive element 332 in a certain section may be set to 1/10 or less. In other words, a ratio between a shortest side and a longest side of the resistive element 332 in a certain section may be 10 or more.

In a pixel configuration of related art, a quenching resistive element is typically located near an APD. In this case, particularly in the case of using minute pixels, the resistive element may be located near a major semiconductor region for inducing avalanche multiplication or a guard ring region for reducing the electric field. In this case, variations in the potential of the quenching element located near the APD or variations in the potential due to avalanche multiplication have an adverse effect on the electrostatic potential of the APD and cause the local concentration of the electric field, which leads to an increase in noise. As illustrated in FIG. 6, in the present exemplary embodiment, the resistive element 332 is formed on the opposite side of the semiconductor substrate as viewed from the cathode wire 331A and the anode wire 331B, thereby enabling the wiring portion to prevent electrostatic interference between the semiconductor substrate and the resistive element 332. In other words, the distance between the resistive element 332 and the first surface of the first semiconductor layer is longer than the distance between the anode wire 331B and the first surface of the first semiconductor layer. This prevents the electrostatic potential of the quenching element and variations in the electrostatic potential from affecting the potential of the APD and prevents the occurrence of local concentration of the electric field, thereby achieving both the reduction of noise and the integration of the pixels 101.

To increase the effect of preventing the electrostatic interference by the wiring portion, at least a part of the resistive element 332 may overlap the wiring portion in a planar view as illustrated in FIG. 7B. To increase the effect of preventing the electrostatic interference by the wiring portion, the thickness of the wiring portion may be greater than the thickness of the resistive element 332. Furthermore, the wiring portion is located to overlap a line connecting a point where a PN junction portion (high electric field region) for inducing avalanche multiplication is located and a certain point in the resistive element 332.

A first resistive element 332 connected to a first avalanche photodiode, which is located in the left one of the two pixels 101 illustrated in FIG. 6 and FIGS. 7A and 7B and a second resistive element 332 connected to a second avalanche photodiode, which is located in the right one of the two pixels 101, are provided at the same height in the wiring structure. In other words, the first resistive element 332 and the second resistive element 332 are formed on a plane parallel to the surface of the first semiconductor layer. It can also be said that the first resistive element 332 and the second resistive element 332 are provided in the same wiring layer within the wiring structure.

In the first exemplary embodiment described above, each photoelectric conversion element 102 has a sensor configuration in which the sensor substrate 11 and the circuit substrate 21 are stacked. Alternatively, each photoelectric conversion element 102 can have a configuration in which circuits, such as the signal processing units 103, are provided on the sensor substrate 11 without using the circuit substrate 21.

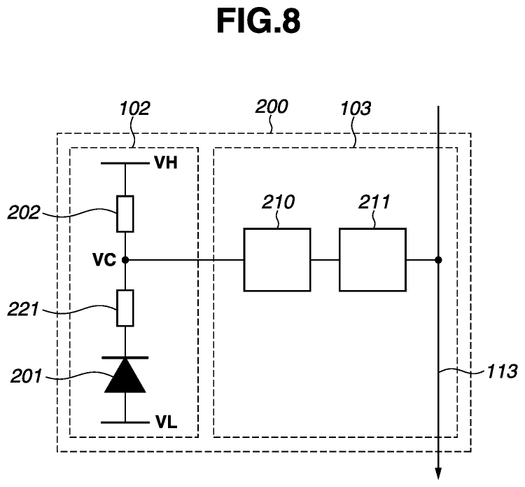

A photoelectric conversion device according to a second exemplary embodiment will be described with reference to FIGS. 8 to 10B. Descriptions of the components common to those of the first exemplary embodiment are omitted, and differences from the first exemplary embodiment will be mainly described. In the second exemplary embodiment, a configuration for facilitating the integration of pixel circuits will be described.

In the second exemplary embodiment, a resistive element 221 is connected in parallel with the resistive element 202 between the APD 201 and the resistive element 202. Unlike in the first exemplary embodiment, the signal amplitude is reduced by the resistance voltage dividing effect. This eliminates the need for using a high-withstand-voltage element at an input stage of the waveform shaping unit 210, thereby facilitating the integration of pixel circuits. The signal amplitude can be further reduced by setting the resistance value of the resistive element 221 to be greater than the resistance value of the resistive element 202. It may be set the sum of the resistance value of the resistive element 202 and the resistance value of the resistive element 221 to a sufficiently high level so as to quench the multiplication current of the APD 201, like in the resistive element 332. For example, the sum of the resistance values may be 50 kOhm or more. In addition, it may be set a voltage division ratio to reduce the signal amplitude to about 0.9 to 0.01. For example, the resistance value of the resistive element 202 can be about kOhm and the resistance value of the resistive element 221 can be about 40 kOhm.

FIG. 8 illustrates an example of a circuit diagram including an equivalent circuit of a pixel unit in the photoelectric conversion device according to the second exemplary embodiment.

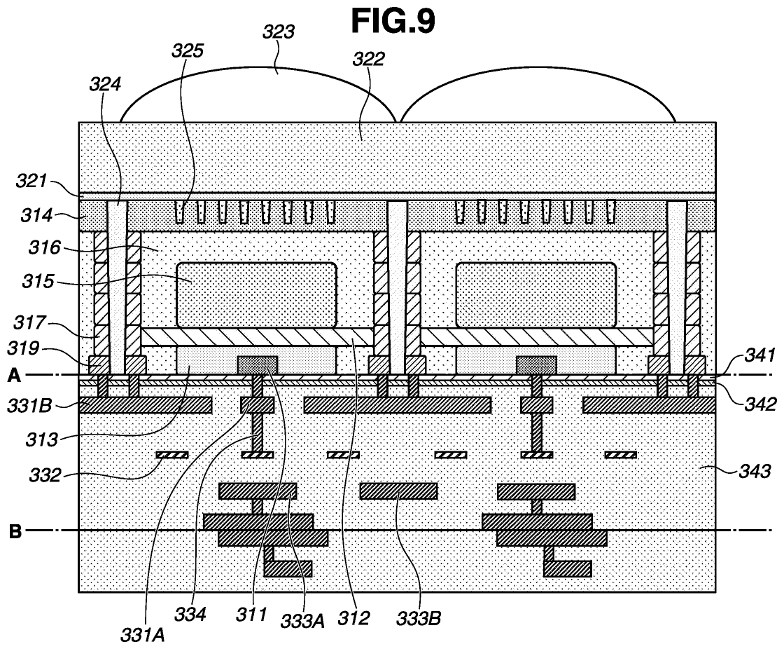

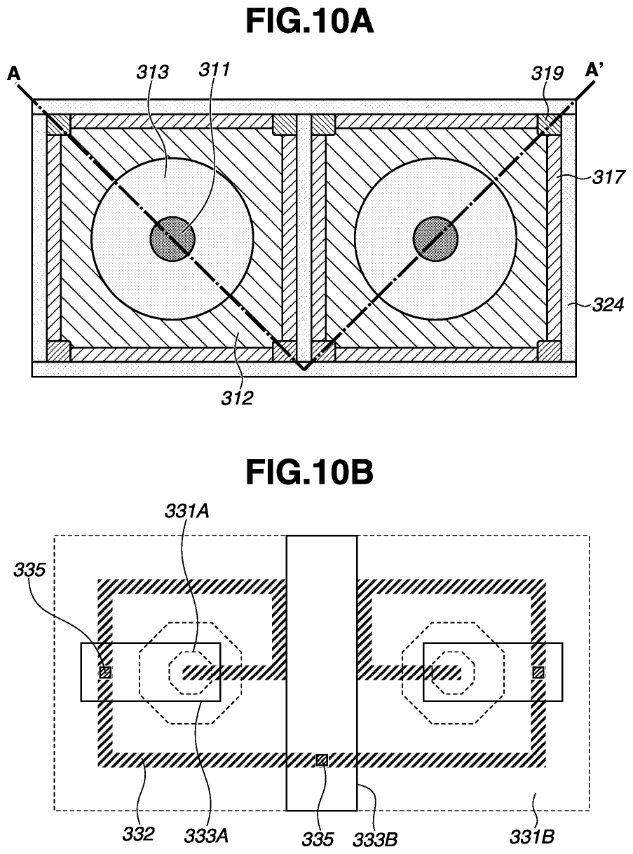

FIG. 9 is a sectional view of the photoelectric conversion elements 102 corresponding to two pixels 101 taken in the direction perpendicular to the substrate surface direction in the photoelectric conversion device according to the second exemplary embodiment. FIG. 9 corresponds to a cross section taken along the line A-A′ illustrated in FIG. 10A. The present exemplary embodiment differs from the first exemplary embodiment in that the wiring portion 333A is not directly connected to the portion where the cathode wire 331A and the resistive element 332 are connected. In other words, the cathode wire 331A and the wiring portion 333A are connected through the resistive element 332.

FIGS. 10A and 10B are plan views each illustrating two pixels 101 in the photoelectric conversion device according to the second exemplary embodiment. FIG. 10A is a plan view of each semiconductor region in a planar view from the surface opposed to the light incident surface. FIG. 10B is a plan view of the wiring portion in a planar view from the surface opposed to the light incident surface.

FIG. 10A is equivalent to FIG. 7A according to the first exemplary embodiment.

As illustrated in FIG. 10B, the resistive element 332 is formed in a fine line pattern, and is electrically connected to the cathode wire 331A and the wiring portion 333B through a via hole. The via hole 335 is formed on an intermediate portion of the resistive element 332 and is electrically connected to the wiring portion 333A. The wiring portion 333A is electrically connected to the signal processing unit 103, which is disposed on the circuit substrate 21, via a connection wire provided for each pixel 101. In the configuration illustrated in FIG. 10B, the cathode wire 331A and the wiring portion 333A overlap each other in a planar view, and the via hole 335 through which the cathode wire 331A and the wiring portion 333A are connected does not overlap the cathode wire 331A or the wiring portion 333A in a planar view. The location of the via hole 335 is not limited to the location illustrated in FIG. 10B.

In the plan views of FIGS. 10A and 10B, elements corresponding to the resistive element 202 and the resistive element 221 illustrated in FIG. 8 are continuously formed as a single resistive element 332. This facilitates the reduction of the layout area of the resistive elements. Alternatively, two resistive elements can be located to be physically isolated from each other. For example, the resistive element 202 and the resistive element 221 can be provided in different wiring layers, and the resistive element 202 and the resistive element 221 can be electrically connected with a member that is mainly made of a material different from the major material of the resistive element 202 and the resistive element 221.

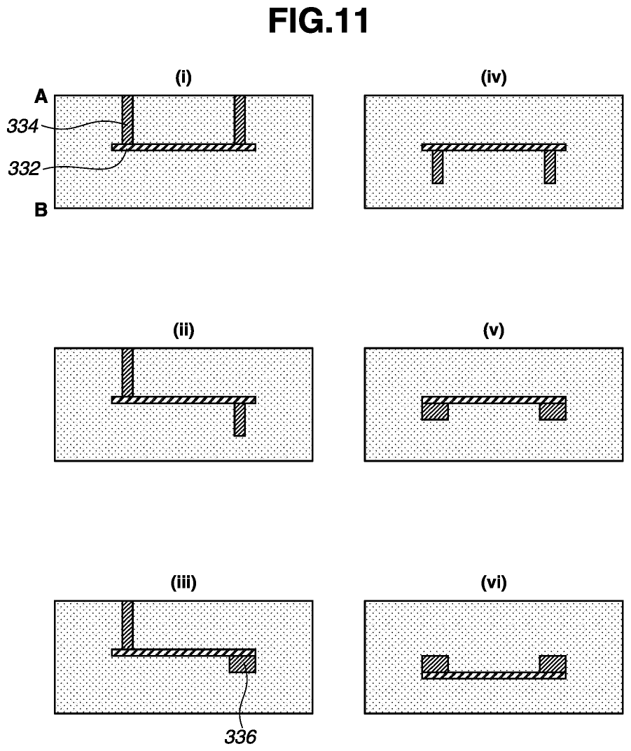

A photoelectric conversion device according to a modified example of the second exemplary embodiment will now be described with reference to FIG. 11.

Descriptions of the components common to those of the first and second exemplary embodiments are omitted, and differences from the second exemplary embodiment will be mainly described. In the present exemplary embodiment, a configuration example of a pixel that can be easily produced will be described.

FIG. 11 illustrates examples of a sectional view of a wiring portion of a pixel according to the modified example of the second exemplary embodiment. FIG. 11 illustrates an example of a method of connecting the resistive element 332 and surrounding electrodes to surfaces corresponding to an A-surface and a B-surface illustrated in FIG. 9. During production, a wiring layer is formed by sequentially stacking layers from the layer nearest the A-surface.

A sectional view (i) in FIG. 11 illustrates that contact plugs (or via holes) 334 are formed and then the resistive element 332 is stacked and formed. In a sectional view (ii) in FIG. 11, the via hole provided on the A-surface side of the resistive element 332 and the via hole provided on the B-surface side of the resistive element 332 coexist. In a sectional view (iii) in FIG. 11, one end of the resistive element 332 functions as a barrier metal on the bottom surface (A-surface) of a wiring portion 336. In a sectional view (iv) in FIG. 11, via holes are formed toward the B-surface from the resistive element 332. In a sectional view (v) in FIG. 11, the both ends of the resistive element 332 function as the barrier metal of the wiring portion 336. In a sectional view (vi) in FIG. 11, a wire is formed and then the resistive element 332 functioning as the barrier metal on the top surface of the wire is formed.

As described above, the electric connection to the resistive element 332 can be established through a contact or a via hole that is used in the typical production method. Alternatively, the resistive element 332 can function as a part of the barrier metal of the wiring portion. A pixel structure that can be easily produced with a high layout area efficiency can be achieved using the typical semiconductor production method in combination.

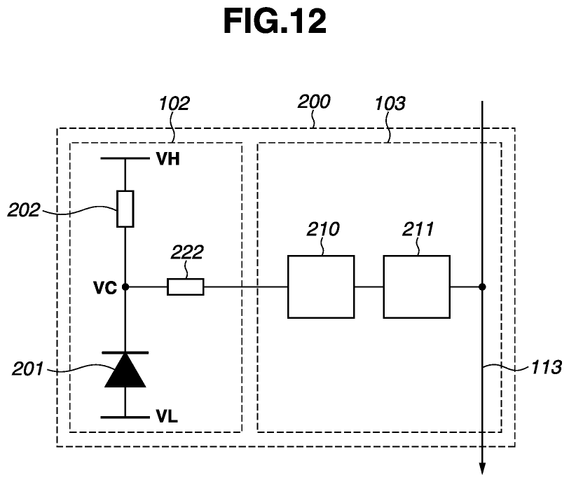

A photoelectric conversion device according to a third exemplary embodiment will now be described with reference to FIGS. 12 to 14B. Descriptions of the components common to those of the first and second exemplary embodiments are omitted, and differences from the second exemplary embodiment will be mainly described. The present exemplary embodiment differs from the first and second exemplary embodiments in that a resistive element 332A and a resistive element 332B have a via-type structure extending in a direction perpendicular to a substrate surface. This configuration further facilitates the integration of the pixels 101.

FIG. 12 illustrates an example of a circuit diagram illustrating an equivalent circuit of a pixel unit in the photoelectric conversion device according to the present exemplary embodiment. In the present exemplary embodiment, a resistive element 222 is provided between the cathode terminal of the APD 201 and the waveform shaping unit 210. The waveform with an amplitude smaller than a signal amplitude of a terminal VC is input to the waveform shaping unit 210 using the low-pass filter effect defined by the resistance of the resistive element 222 and the input capacitance of the waveform shaping unit 210. This eliminates the need for using a high-withstand-voltage element at the input stage of the waveform shaping unit 210, thereby facilitating the integration of pixel circuits. Since only the resistive element 202 is connected in series with the APD 201, dead time can be easily reduced compared to the second exemplary embodiment.

In the configuration illustrated in FIG. 12, three resistive elements, including a resistive element located between the APD 201 and the terminal VC, can be provided.

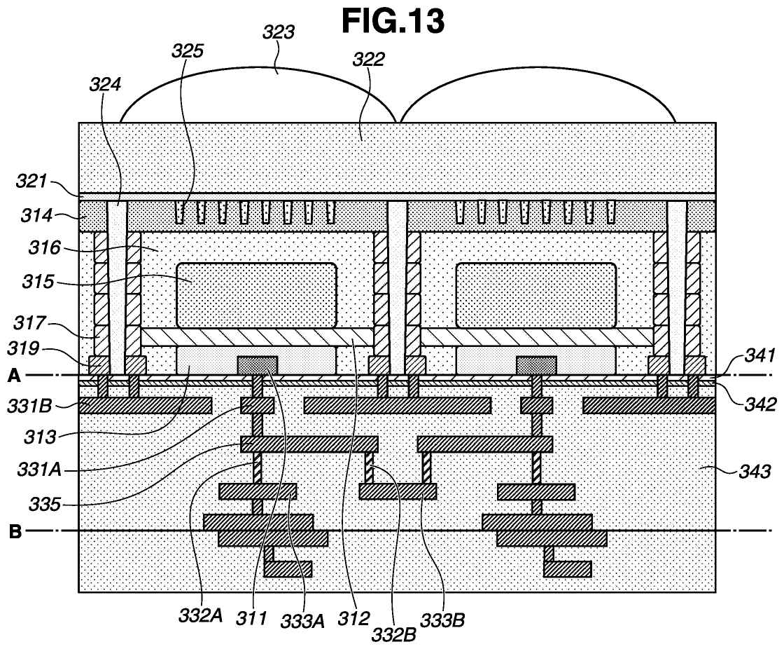

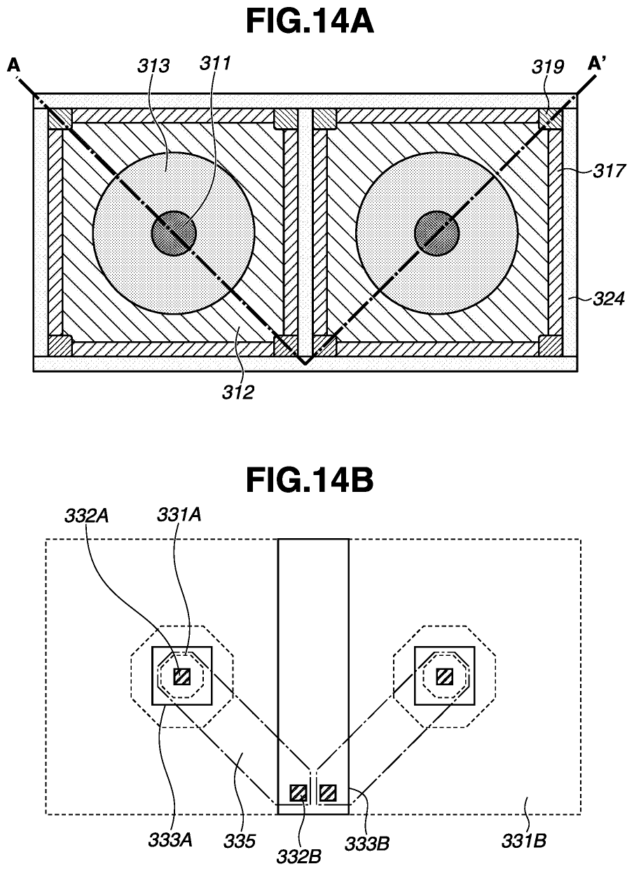

FIG. 13 is a sectional view of the photoelectric conversion elements 102 corresponding to two pixels 101 taken in the direction perpendicular to the substrate surface direction in the photoelectric conversion device according to the third exemplary embodiment. FIG. 13 corresponds to a cross section taken along the line A-A′ illustrated in FIG. 14A.

The cathode wire 331A is connected to a wiring portion 335 through a via hole made of a normal metal material such as copper (Cu). The wiring portion 335 is connected to the wiring portion 333A and the wiring portion 333B through the resistive element 332A and the resistive element 332B, respectively, that are via-type resistive elements using a high-resistance material. A via-type resistive element has a smaller diameter than a normal via hole. A material for a barrier layer of the via-type resistive element can be different from a material for a barrier layer of a normal via hole. The thickness of an interlayer film provided with the via-type resistive element may be greater than the thickness of an interlayer film provided with a normal via hole.

FIGS. 14A and 14B are plan views each illustrating two pixels 101 in the photoelectric conversion device according to the third exemplary embodiment. FIG. 14A is a plan view of each semiconductor region in a planar view from the surface opposed to the light incident surface. FIG. 14B is a plan view of the wiring portion in a planar view from the surface opposed to the light incident surface.

FIG. 14A is equivalent to FIG. 7A according to the first exemplary embodiment.

As illustrated in FIG. 14B, the resistive element 332A is formed in a via-type pattern, and is electrically connected to the wiring portion 335 and the wiring portion 333A. The resistive element 332B is formed in a via-type pattern, and is electrically connected to the wiring portion 335 and the wiring portion 333B. The wiring portion 333A is electrically connected to the signal processing unit 103, which is disposed on the circuit substrate 21, via a connection wire provided for each pixel 101. In the present exemplary embodiment, via-type resistive elements corresponding to the resistive element 202 and the resistive element 222 illustrated in FIG. 12 are disposed in the same plane parallel to the substrate surface, but instead can be stacked and formed in the direction perpendicular to the substrate surface.

In the present exemplary embodiment, the use of via-type resistive elements makes it possible to improve the layout area efficiency and facilitate the integration of the pixels 101.

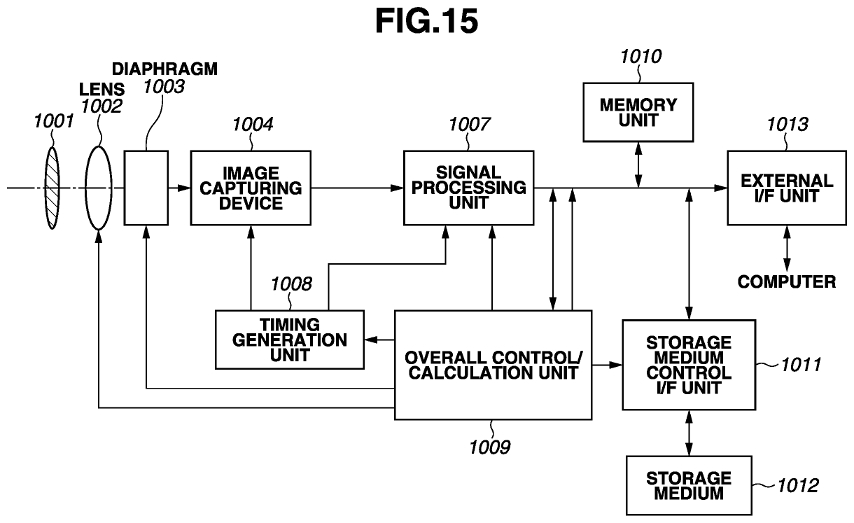

A photoelectric conversion system according to a fourth exemplary embodiment will now be described with reference to FIG. 15. FIG. 15 is a block diagram illustrating a schematic configuration of the photoelectric conversion system according to the present exemplary embodiment.

The photoelectric conversion devices according to the first to third exemplary embodiments can be applied to various photoelectric conversion systems. Examples of various applicable photoelectric conversion systems include a digital still camera, a digital camcorder, a monitoring camera, a copying machine, a facsimile machine, a mobile phone, an on-vehicle camera, and an observation satellite. The various applicable photoelectric conversion systems also include a camera module including an optical system such as a lens and an image capturing device. FIG. 15 is a block diagram illustrating a digital still camera as an example of these photoelectric conversion systems.

The photoelectric conversion system illustrated in FIG. 15 includes an image capturing device 1004 as an example of the photoelectric conversion device, and a lens 1002 that forms an optical image of an object on the image capturing device 1004. The photoelectric conversion system further includes a diaphragm 1003 configured to change the amount of light passing through the lens 1002, and a barrier 1001 for protecting the lens 1002. The lens 1002 and the diaphragm 1003 are optical systems for focusing light on the image capturing device 1004. The image capturing device 1004 is any of the photoelectric conversion devices according to the above-described exemplary embodiments, and converts an optical image formed by the lens 1002 into an electric signal.

The photoelectric conversion system further includes a signal processing unit 1007 serving as an image generation unit that generates an image by performing processing on an output signal output from the image capturing device 1004. The signal processing unit 1007 performs an operation of performing various correction and compression processes, as needed, and outputting image data. The signal processing unit 1007 can be formed on a semiconductor substrate on which the image capturing device 1004 is provided, or can be formed on another semiconductor substrate different from the semiconductor substrate on which the image capturing device 1004 is provided.

The photoelectric conversion system further includes a memory unit 1010 for temporarily storing image data, and an external interface (I/F) unit 1013 for communicating with an external computer or the like. The photoelectric conversion system further includes a storage medium 1012, such as a semiconductor memory, for recording or reading out captured image data, and a storage medium control OF unit 1011 for recording data on the storage medium 1012 or reading out data from the storage medium 1012. The storage medium 1012 can be incorporated in the photoelectric conversion system, or can be detachably attached to the photoelectric conversion system.

The photoelectric conversion system further includes an overall control/calculation unit 1009 that controls various calculations and overall operations of the digital still camera, and a timing generation unit 1008 that outputs various timing signals to the image capturing device 1004 and the signal processing unit 1007. The timing signals and the like can be input from an external device. The photoelectric conversion system may include at least the image capturing device 1004 and the signal processing unit 1007 that processes the output signal output from the image capturing device 1004.

The image capturing device 1004 outputs a captured image signal to the signal processing unit 1007. The signal processing unit 1007 performs predetermined signal processing on the captured image signal output from the image capturing device 1004, and outputs image data. The signal processing unit 1007 generates an image using the captured image signal.

According to the present exemplary embodiment as described above, the photoelectric conversion system can be achieved to which any of the photoelectric conversion devices (image capturing devices) according to the above-described exemplary embodiments is applied.

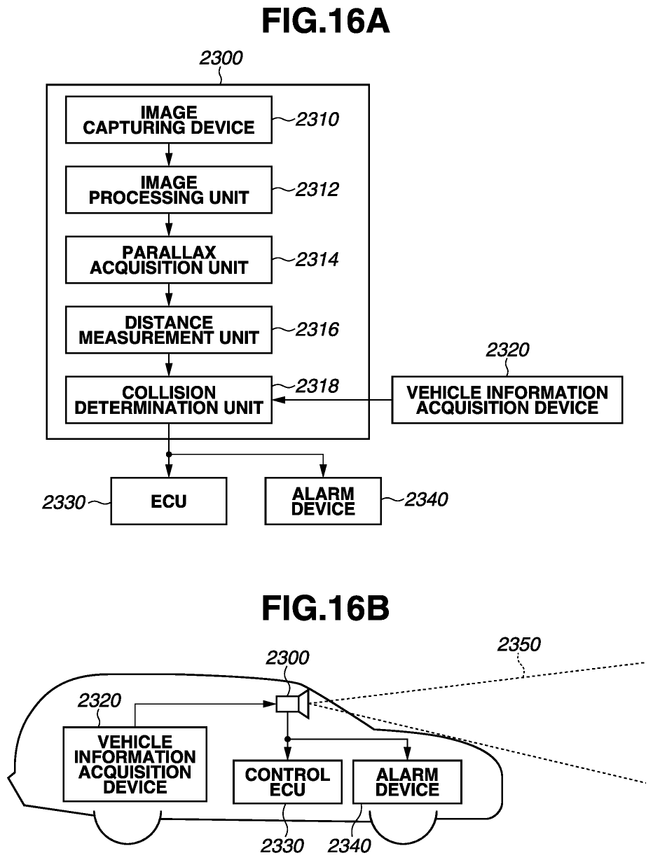

A photoelectric conversion system and a moving body according to a fifth exemplary embodiment will now be described with reference to FIGS. 16A and 16B. FIG. 16A illustrates a configuration example of the photoelectric conversion system according to the present exemplary embodiment. FIG. 16B illustrates a configuration example of the moving body according to the fifth exemplary embodiment.

FIG. 16A illustrates an example of a photoelectric conversion system for an on-vehicle camera. A photoelectric conversion system 2300 includes an image capturing device 2310. The image capturing device 2310 is any one of the photoelectric conversion devices according to the above-described exemplary embodiments. The photoelectric conversion system 2300 includes an image processing unit 2312 that performs image processing on a plurality of pieces of image data acquired by the image capturing device 2310, and a parallax acquisition unit 2314 that calculates a parallax (phase difference between parallax images) based on the plurality of pieces of image data acquired by the photoelectric conversion system 2300. The photoelectric conversion system 2300 also includes a distance measurement unit 2316 that calculates a distance to a target object based on the calculated parallax, and a collision determination unit 2318 that determines whether there is a possibility of collision based on the calculated distance. The parallax acquisition unit 2314 and the distance measurement unit 2316 are examples of a distance information acquisition unit that acquires distance information indicating a distance to a target object. The distance information indicates information about a parallax, a defocus amount, a distance to a target object, and the like. The collision determination unit 2318 can determine the possibility of collision using any one of the pieces of distance information. The distance information acquisition unit can be implemented by an exclusively designed hardware or software module.

Alternatively, the distance information acquisition unit can be implemented by, for example, a field-programmable gate array (FPGA), or an application-specific integrated circuit (ASIC), or a combination thereof.

The photoelectric conversion system 2300 is connected to a vehicle information acquisition device 2320, and is configured to acquire vehicle information, such as a vehicle speed, a yaw rate, and a steering angle. The photoelectric conversion system 2300 is also connected to an engine control unit (ECU) 2330 serving as a control unit that outputs a control signal for applying a braking force to a vehicle, based on the determination result of the collision determination unit 2318. The photoelectric conversion system 2300 is also connected to an alarm device 2340 that issues an alarm to a driver based on the determination result of the collision determination unit 2318. For example, in a case where there is a high possibility of collision based on the determination result of the collision determination unit 2318, the ECU 2330 performs vehicle control to avoid a collision or reduce damage by, for example, applying brakes, releasing an accelerator, or restraining engine power. The alarm device 2340 warns a user by, for example, generating an alarm sound, displaying alarm information on a screen of a navigation system or the like, or applying vibrations to a seat belt or a steering wheel.

In the present exemplary embodiment, the photoelectric conversion system 2300 captures images of an area around the vehicle such as a front side or a rear side of the vehicle. FIG. 16B illustrates the photoelectric conversion system 2300 for capturing an image of the front side (an imaging range 2350) of the vehicle. The vehicle information acquisition device 2320 sends an instruction to the photoelectric conversion system 2300 or the image capturing device 2310. This configuration can further improve the accuracy of ranging.

While the example of control for avoiding a collision with another vehicle is described above, the present exemplary embodiment is also applicable to control for automated driving to follow another vehicle, control for automated driving not to stray from a traffic lane, and the like. The photoelectric conversion system 2300 is not limited to the vehicle such as an automobile. The photoelectric conversion system 2300 is also applicable to, for example, a moving body (traveling apparatus), such as a ship, an airplane, or an industrial robot. The photoelectric conversion system 2300 is widely applicable not only to the moving body, but also to an apparatus that uses object recognition, such as an intelligent transport system (ITS).

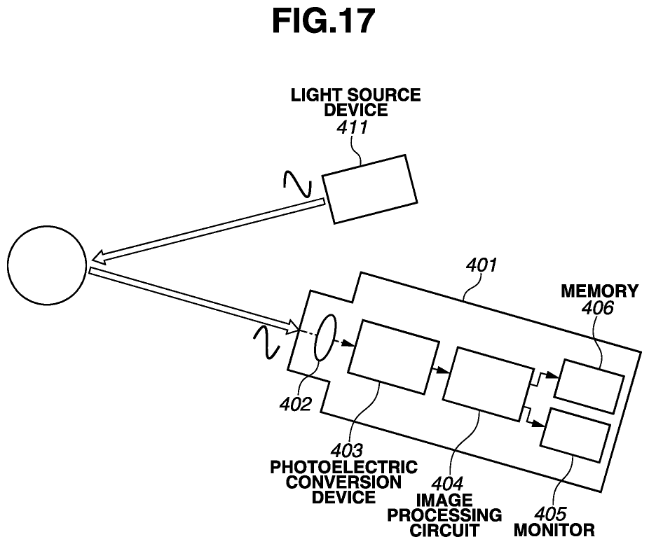

A photoelectric conversion system according to a sixth exemplary embodiment will now be described with reference to FIG. 17. FIG. 17 is a block diagram illustrating a configuration example of a distance image sensor serving as the photoelectric conversion system according to the present exemplary embodiment.

As illustrated in FIG. 17, a distance image sensor 401 includes an optical system 402, a photoelectric conversion device 403, an image processing circuit 404, a monitor 405, and a memory 406. The distance image sensor 401 projects light toward an object from a light source device 411, and receives light (modulated light or pulse light) reflected on the surface of the object, and thereby a distance image corresponding to the distance to the object is obtained.

The optical system 402 includes one or more lenses. The optical system 402 guides image light (incident light) from the object to the photoelectric conversion device 403, and forms an image on a light-receiving surface (sensor portion) of the photoelectric conversion device 403.

As the photoelectric conversion device 403, any one of the photoelectric conversion devices according to the above-described exemplary embodiments is applied. The photoelectric conversion device 403 supplies a distance signal indicating the distance obtained based on the received light signal to the image processing circuit 404.

The image processing circuit 404 performs image processing to construct the distance image based on the distance signal supplied from the photoelectric conversion device 403. The distance image (image data) obtained by the image processing may be supplied to the monitor 405 to be displayed on the monitor 405, or may be supplied to the memory 406 to be stored (recorded).

The distance image sensor 401 having an above-described configuration can acquire, for example, a more accurate distance image with an improvement in pixel characteristics by applying any of the above-described photoelectric conversion devices.

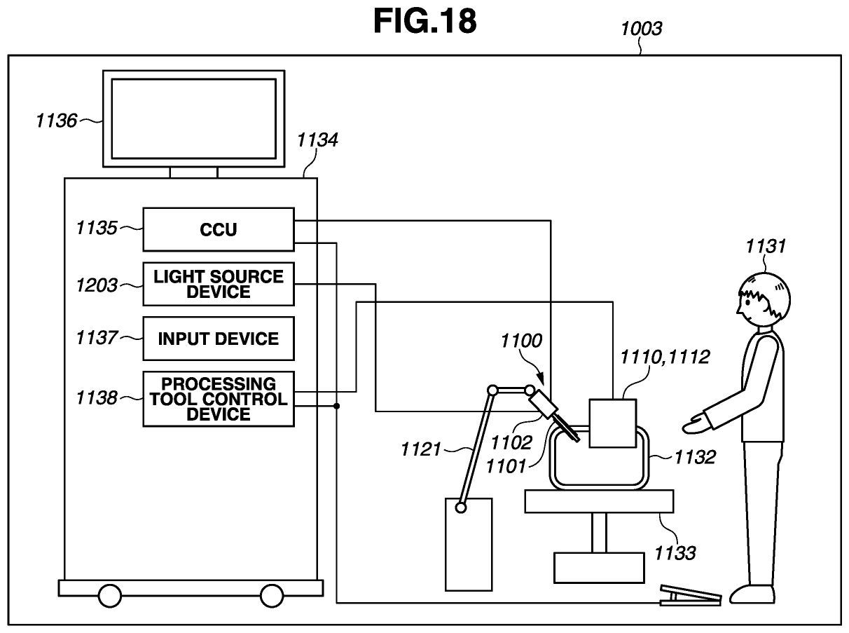

A photoelectric conversion system according to a seventh exemplary embodiment will now be described with reference to FIG. 18. FIG. 18 illustrates a schematic configuration example of an endoscopic surgery system as the photoelectric conversion system according to the eighth exemplary embodiment.

FIG. 18 illustrates a state where an operator (doctor) 1131 performs a surgery on a patient 1132 on a patient bed 1133 using an endoscopic surgery system. As illustrated in FIG. 18, the endoscopic surgery system includes an endoscope 1100, a surgical instrument 1110, and a cart 1134 on which various devices for microscopically controlled surgery are placed.

The endoscope 1100 includes a lens barrel 1101 and a camera head 1102. A predetermined length of region of the endoscope 1100 from a distal end of the lens barrel 1101 is inserted into the body cavity of the patient 1132. The camera head 1102 is connected to a proximal end of the lens barrel 1101. In the illustrated example, the endoscope 1100 is formed as a so-called hard mirror including the hard lens barrel 1101. Alternatively, the endoscope 1100 can be formed as a so-called soft mirror including a soft lens barrel.

The distal end of the lens barrel 1101 is provided with an opening into which an objective lens is fit. A light source device 1203 is connected to the endoscope 1100. Light generated by the light source device 1203 is guided to the distal end of the lens barrel 1101 by a light guide extending in the lens barrel 1101. The light is radiated toward an observation target in the body cavity of the patient 1132 through the objective lens. The endoscope 1100 can be a forward-viewing endoscope, an oblique-viewing endoscope, or a side-viewing endoscope.

In the camera head 1102, an optical system and a photoelectric conversion device are provided, and reflected light (observation light) from the observation target is focused on the photoelectric conversion device by the optical system. The observation light is photoelectrically converted by the photoelectric conversion device, thereby generating an electric signal corresponding to the observation light, or an image signal corresponding to the observation light. As the photoelectric conversion device, any of the photoelectric conversion devices according to the above-described exemplary embodiments can be used. The image signal is transmitted to a camera control unit (CCU) 1135 as raw data.

The CCU 1135 is composed of a central processing unit (CPU), a graphics processing unit (GPU), or the like, and controls operations of the endoscope 1100 and a display device 1136 in an integrated manner. The CCU 1135 also receives the image signal from the camera head 1102, and performs various image processing for displaying an image based on the image signal, such as development processing (demosaicing processing), on the image signal.

The display device 1136 displays an image based on the image signal on which image processing is performed by the CCU 1135 under control of the CCU 1135.

The light source device 1203 is composed of a light source, such as a light-emitting diode (LED), and supplies irradiated light to the endoscope 1100 when an image of a surgery site is captured.

An input device 1137 is an input OF for the endoscopic surgery system. The user can input various information and instructions to the endoscopic surgery system through the input device 1137.

A processing tool control device 1138 controls driving of an energy processing tool 1112 for cauterization or incision of a tissue, sealing of a blood vessel, or the like.

The light source device 1203 that supplies irradiated light to the endoscope 1100 when an image of a surgery site is captured can be composed of, for example, an LED, a laser light source, or a white light source formed of a combination of these. In a case where the white light source is formed of a combination of RGB laser light sources, an output intensity and an output timing of each color (each wavelength) can be accurately controlled. Thus, the light source device 1203 can adjust the white balance of the captured image. In this case, laser light from each of the RGB laser light sources is radiated to the observation target by time division, and driving of an image sensor of the camera head 1102 is controlled in synchronization with the irradiation timing, thereby making it possible to capture images respectively corresponding to RGB laser light beams by time division. According to this method, a color image can be obtained without providing any color filter in the image sensor.

Driving of the light source device 1203 can be controlled such that the intensity of light to be output is changed at predetermined time intervals. Driving of the image sensor of the camera head 1102 is controlled in synchronization with the timing of changing the light intensity to obtain images by time division and combine the images, thereby making it possible to form an image with a high dynamic range without causing a so-called black underexposure picture or a white-out.

The light source device 1203 can also be configured to supply light in a predetermined wavelength band corresponding to a special light observation. In the special light observation, for example, the wavelength dependence of absorption of light in a body tissue is used. Specifically, an image of a predetermined tissue, such as a blood vessel on a mucous surface, is captured with a high contrast by radiating light with a bandwidth narrower than that of irradiated light (i.e., white light) in a normal observation.

Alternatively, in the special light observation, a fluorescent observation can be performed for obtaining an image by using fluorescence generated by radiating excitation light. In the fluorescent observation, for example, fluorescence from a body tissue can be observed by radiating excitation light to the body tissue, or a fluorescence image can be obtained by locally injecting reagent, such as indocyanine green (ICG), into a body tissue and radiating excitation light corresponding to the fluorescence wavelength of the reagent to the body tissue. The light source device 1203 can be configured to supply narrow-band light and/or excitation light compatible with the special light observation.

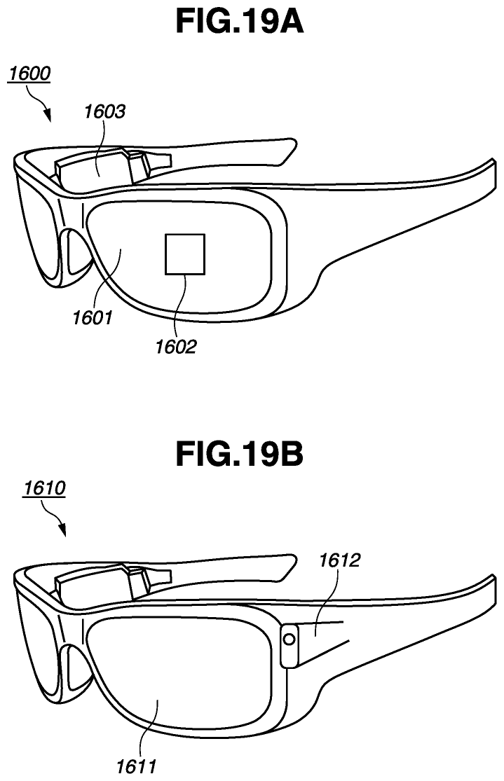

A photoelectric conversion system according to an eighth exemplary embodiment will now be described with reference to FIGS. 19A and 19B. FIG. 19A illustrates glasses 1600 (smart glasses) as an example of the photoelectric conversion system according to the present exemplary embodiment. The glasses 1600 include a photoelectric conversion device 1602. The photoelectric conversion device 1602 is any one of the photoelectric conversion devices according to the above-described exemplary embodiments. On the back surface of a lens 1601, a display device including a light-emitting device, such as an organic LED (OLED) or an LED, can be provided. One or more photoelectric conversion devices 1602 can be provided. A combination of various types of photoelectric conversion devices can also be used. The layout position of the photoelectric conversion device 1602 is not limited to the layout position illustrated in FIG. 19A.

The glasses 1600 further include a control device 1603. The control device 1603 functions as a power supply that supplies power to the photoelectric conversion device 1602 and the above-described display device. The control device 1603 controls operations of the photoelectric conversion device 1602 and the display device. The lens 1601 is provided with an optical system to focus light on the photoelectric conversion device 1602.

FIG. 19B illustrates glasses 1610 (smart glasses) according to an application example. The glasses 1610 include a control device 1612. The glasses 1610 also include a photoelectric conversion device corresponding to the photoelectric conversion device 1602 and a display device. A lens 1611 is provided with the photoelectric conversion device in the control device 1612, and an optical system for projecting light emitted from the display device. An image is projected on the lens 1611. The control device 1612 functions as a power supply that supplies power to each of the photoelectric conversion device and the display device, and controls operations of the photoelectric conversion device and the display device. The control device 1612 can include a line-of-sight detection unit that detects the line of sight of a user. An infrared ray can be used to detect the line of sight. An infrared light-emitting unit emits infrared light to an eyeball of the user who is gazing at a display image. Reflected light of the emitted infrared light from the eyeball is detected by an image capturing unit including a light-receiving element, and thereby a captured image of the eyeball is obtained. Provision of a reduction unit to reduce light from the infrared light-emitting unit to the display unit in a planar view makes it possible to reduce the deterioration in image quality.

The line of sight of the user on the display image is detected from the captured image of the eyeball obtained by capturing infrared light. Any known technique can be applied as a method of detecting the line of sight using a captured image of an eyeball. For example, a line-of-sight detection method based on a Purkinje image by reflection of irradiated light on corneas can be used.

More specifically, line-of-sight detection processing based on a pupil center corneal reflection method is performed. The use of the pupil center corneal reflection method allows calculation of a line-of-sight vector representing the direction (rotation angle) of an eyeball based on the image of the pupil and the Purkinje image included in the captured image of the eyeball, and thereby the line of sight of the user is detected.

The display device according to the present exemplary embodiment may include a photoelectric conversion device including a light-receiving element, and control a display image on the display device based on line-of-sight information about the user from the photoelectric conversion device.

Specifically, the display device determines a first field-of-view region at which the user gazes, and a second field-of-view region other than the first field-of-view region based on the line-of-sight information. The first field-of-view region and the second field-of-view region can be determined by a control device for the display device. Alternatively, the first field-of-view region and the second field-of-view region determined by an external control device can be received. In a display region of the display device, the display resolution of the first field-of-view region can be controlled to be higher than the display resolution of the second field-of-view region. In other words, the resolution of the second field-of-view region can be set to be lower than the resolution of the first field-of-view region.

The display region includes a first display region and a second display region different from the first display region. One of the first display region and the second display region with a higher priority than the other can be determined based on the line-of-sight information. The first field-of-view region and the second field-of-view region can be determined by the control device for the display device. Alternatively, the first field-of-view region and the second field-of-view region determined by an external control device can be received. The resolution of the higher-priority region can be controlled to be higher than the resolution of the region other than the higher-priority region. In other words, the resolution of the region with a relatively low priority can be lowered.

An artificial intelligence (AI) can be used to determine the first field-of-view region or the higher-priority region. The AI can be a model configured to estimate a line-of-sight angle and a distance to a target object in the line of sight by using teacher data having the eyeball image and the direction in which the eyeball has actually been looking. An AI program can be included in the display device, the photoelectric conversion device, or an external device. If the AI program is included in the external device, the AI program is transmitted to the display device via communication.

In display control based on visual detection, smart glasses further including a photoelectric conversion device that captures an image of an outside can be suitably applied. The smart glasses are configured to display information about the captured image of the outside in real time.

The disclosure is not limited to the above-described exemplary embodiments, and can be modified in various ways.

For example, an example where a part of the configuration according to any of the exemplary embodiments is added to any of the other exemplary embodiments, and an example where a part of the configuration according to any of the exemplary embodiments is replaced with a part of the configuration according to any of the other exemplary embodiments are also included in the exemplary embodiments of the disclosure.

The photoelectric conversion systems according to the fourth and fifth exemplary embodiments described above are examples of the photoelectric conversion system to which any of the photoelectric conversion devices according to the exemplary embodiments can be applied. The photoelectric conversion system to which any of the photoelectric conversion device according to the exemplary embodiments can be applied is not limited to the configurations illustrated in FIGS. 15 to 16B. This also holds true for the ToF system according to the sixth exemplary embodiment, the endoscope according to the seventh exemplary embodiment, and the smart glasses according to the eighth exemplary embodiment.

The photoelectric conversion devices according to the above-described exemplary embodiments are also applicable to sensors in an automobile. For example, the photoelectric conversion devices can be applied to sensors used to detect the face of a driver, detect the expression of the driver, and detect the line of sight of the driver. The use of an output from such sensors makes it possible to detect, for example, a driver's impaired attention, drowsy driving, or fainting. Such sensors can also be used to identify the driver.

The above-described exemplary embodiments are merely specific examples for carrying out the disclosure. The technical scope of the disclosure should not be interpreted in a limited way. That is, the disclosure can be carried out in various forms without departing from the technical idea or the main features thereof.

According to an aspect of the disclosure, it is possible to achieve both the reduction of noise and the integration of pixels in a photoelectric conversion device.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-104637, filed Jun. 29, 2022, which is hereby incorporated by reference herein in its entirety.

What is claimed is:

1. A device including a first substrate including a first layer including a first surface and a second surface, and a first wiring structure located on the first layer, the device comprising:
at least one avalanche photodiode located on the first layer; and
a resistive element connected to the avalanche photodiode,
wherein the first wiring structure includes a first wire configured to supply a first voltage to the avalanche photodiode, and a second wire configured to supply a second voltage to the avalanche photodiode, and
wherein a distance between the resistive element and the first surface of the first layer is greater than each of a distance between the first wire and the first surface of the first layer and a distance between the second wire and the first surface of the first layer.

2. The device according to claim 1, wherein the first substrate further includes a second layer stacked on the first substrate.

3. The device according to claim 2, further comprising a shaping unit configured to shape a waveform of an output signal from the avalanche photodiode, the shaping unit being located on the second layer.

4. The device according to claim 1,
wherein the at least one avalanche photodiode comprises a plurality of avalanche photodiodes, and
wherein a first resistive element connected to a first avalanche photodiode and a second resistive element connected to a second avalanche photodiode are located on a same plane parallel to a surface of the first layer, the first avalanche photodiode and the second avalanche photodiode being included in the plurality of avalanche photodiodes.

5. The device according to claim 1, wherein the resistive element includes either polycrystalline silicon or amorphous silicon.

6. The device according to claim 1, wherein the resistive element includes a metal thin-film material.

7. The device according to claim 1, wherein the resistive element includes a ceramic material.

8. The device according to claim 1, wherein the resistive element includes an organic material.

9. The device according to claim 1, wherein a ratio between a shortest side and a longest side of the resistive element is more than or equal to 10.

10. The device according to claim 1, wherein the resistive element includes a material with a resistivity greater than a resistivity of a major material of the first wire.

11. The device according to claim 1, wherein the resistive element includes a material with a resistivity greater than a resistivity of a major material in a via hole configured to supply a voltage to the avalanche photodiode.

12. The device according to claim 1, wherein the resistive element overlaps a cathode of the avalanche photodiode in a planar view.

13. The device according to claim 1, wherein a resistive element is connected to each of a cathode and an anode of the avalanche photodiode.

14. The device according to claim 2, wherein the resistive element extends in a direction perpendicular to a substrate surface of the first substrate.

15. The device according to claim 1, wherein the first wire and the second wire are located on the first substrate, the first wire and the second wire serving as two channels configured to supply voltages to each of a cathode and an anode of the avalanche photodiode.

16. The device according to claim 1, wherein at least a part of the first wire overlaps the resistive element in a planar view.

17. The device according to claim 2, wherein a thickness of the resistive element in a direction perpendicular to the first substrate is smaller than a thickness of the first wire in the direction perpendicular to the first substrate.

18. The device according to claim 1, wherein the first wire is located on a line connecting a multiplication region of the avalanche photodiode and a certain point in the resistive element.

19. The device according to claim 1, wherein a contact plug is connected to both a lower side of the resistive element and an upper side of the resistive element.

20. The device according to claim 1, wherein the resistive element has a resistance value of more than or equal to 50 kilo ohms.

21. A system comprising:
the device according to claim 1; and
a processing unit configured to form an image using a signal output from the device.

22. A moving body comprising:
the device according to claim 1; and
a control unit configured to control traveling of the moving body using a signal output from the device.
